(19) United States
(12) Patent Application Publication
(10) Pub. No.: US 2008/0205130 A1
(43) Pub. Date: Aug. 28, 2008

(54) MRAM FREE LAYER SYNTHETIC ANTIFERROMAGNET STRUCTURE AND METHODS

(75) Inventors: Jijun Sun, Chandler, AZ (US); Nicholas D. Rizzo, Gilbert, AZ (US); Jon M. Slaughter, Tempe, AZ (US)

Correspondence Address: INGRASSIA FISHER & LORENZ, P.C. (FS), 7010 E. COCHISE ROAD, SCOTTSDALE, AZ, 85253, US

(73) Assignee: FREESCALE SEMICONDUCTOR, INC., Austin, TX (US)

(21) Appl. No.: 11/679,982

(22) Filed: Feb. 28, 2007

(51) Int. Cl. G11C 11/15; H01L 21/00; H01L 29/82

(52) U.S. Cl. 365/173; 257/421; 438/3; 257/E29.323; 257/E21.001

(57) ABSTRACT

A magnetic tunnel junction (MTJ) structure for use with toggle MRAM devices and the like includes a tunnel barrier layer and a synthetic antiferromagnet (SAF) structure formed on the tunnel barrier layer, wherein the SAF includes a plurality (e.g., three or more) ferromagnetic layers antiferromagnetically or ferromagnetically coupled by a plurality of respective coupling layers. The bottom ferromagnetic layer adjacent the tunnel barrier layer has a high spin polarization and a high intrinsic anisotropy field (Hₖᵢ) while one or more of the remaining ferromagnetic layers has a low intrinsic anisotropy field Hₖᵢ.

### TECHNICAL FIELD

The present invention generally relates to magnetoresistive random access memory (MRAM) such as toggle MRAM structures, and more particularly relates to synthetic antiferromagnet (SAF) structures used in such MRAM devices.

### BACKGROUND

Magnetoresistive random access memory (MRAM) technology combines magnetoresistive components with standard silicon-based microelectronics to achieve non-volatility, high-speed operation, and excellent read/write endurance. In a standard MRAM device, information is stored in the magnetization directions of free magnetic layer in individual magnetic tunnel junctions (MTJ). Referring to FIG. 1, an MTJ 100 generally includes a tunneling barrier 108 between two ferromagnetic layers: free ferromagnetic layer 106, and fixed ferromagnetic layer 110. Each layer 106 and 110 may comprise multiple ferromagnetic layers (a synthetic antiferromagnet, or “SAF”) or a single layer. The fixed layer is typically formed over a pinning layer 120. The structure is typically formed over a seed layer 112 and includes a cap layer 130 over the free layer, and is positioned between two electrodes 102 and 114.

In a standard MRAM, the bit state is programmed to a “1” or “0” using applied magnetic fields generated by currents flowing along two programming lines. The applied magnetic fields selectively switch the magnetic moment direction of free layer 106 for the bit at the intersection of two programming lines as needed to program the bit state. When the magnetic moment directions of free layer 106 and fixed layer 110 are aligned in the same direction, and a voltage is applied across MTJ 100, a lower resistance is measured than when the magnetic moment directions of layers 106 and 110 are set in opposite directions.

For toggle MRAM devices, free layer 106 may consist of a standard SAF as shown in FIG. 2, wherein two ferromagnetic layers 202 and 206 are antiferromagnetically coupled via a coupling layer 204. Magnetization directions are shown by the arrows in layers 202 and 206.

The switching field (H_{sw}) necessary for a toggle transition in a toggle MRAM is related to the magnetic properties of the patterned SAF free layer according to the relationship H_{sw}=\sqrt{HₖHₛₐₜ}, where Hₖ is the anisotropy field of the two ferromagnetic layers in the SAF and Hₛₐₜ is the saturation magnetic field of the SAF. More specifically, Hₖ is the total anisotropy of the ferromagnetic layers in the SAF, which includes contributions from the intrinsic material anisotropy Hₖᵢ, and from shape anisotropy Hₖₛ, so that Hₖ=Hₖᵢ+Hₖₛ. For reliable toggle switching, the vector sum of the applied field pulses should be at least H_{sw} and less than Hₛₐₜ. Lower H_{sw} is desirable to minimize the power needed for switching, but decreasing H_{sw} by reducing Hₛₐₜ has limited usefulness in memory arrays because the operating window (Hₛₐₜ−H_{sw}) shrinks and eventually becomes too small, especially for high Hₖ magnetic materials. This limits the applications in which the toggle MRAM may be used. For example, the operating temperature range is limited because Hₛₐₜ decreases with increasing temperature.

Free-layer ferromagnetic materials that give rise to high magnetoresistance (MR) due to their large spin polarization, such as NiFeCo and CoFeB, generally have high intrinsic Hₖᵢ. Hereinafter, the term “anisotropy field” refers to the intrinsic anisotropy Hₖᵢ. However, for standard toggle MRAM free layers, such ferromagnetic materials with high Hₖᵢ lead to high switching field for the same Hₛₐₜ, or to a small operating window for the same H_{sw}.

It is therefore desirable to provide improved SAF structures for MRAM devices that exhibit a high MR while offering a wide operating window. Other desirable features and characteristics of the present invention will become apparent from the subsequent detailed description of the invention and the appended claims, taken in conjunction with the accompanying drawings and this background of the invention.

### BRIEF DESCRIPTION OF THE DRAWINGS

The present invention will hereinafter be described in conjunction with the following drawing figures, wherein like numerals denote like elements, and

FIG. 1 is a conceptual cross-sectional view of a prior art standard toggle MRAM MTJ;

FIG. 2 is a cross-sectional view of a prior art SAF;

FIG. 3 is a conceptual cross-sectional view of a SAF in accordance with one embodiment;

FIG. 4 is a conceptual cross-sectional view of a SAF in accordance with an alternate embodiment; and

FIGS. 5 and 6 are conceptual cross-sectional views of a SAF in accordance with various embodiments.

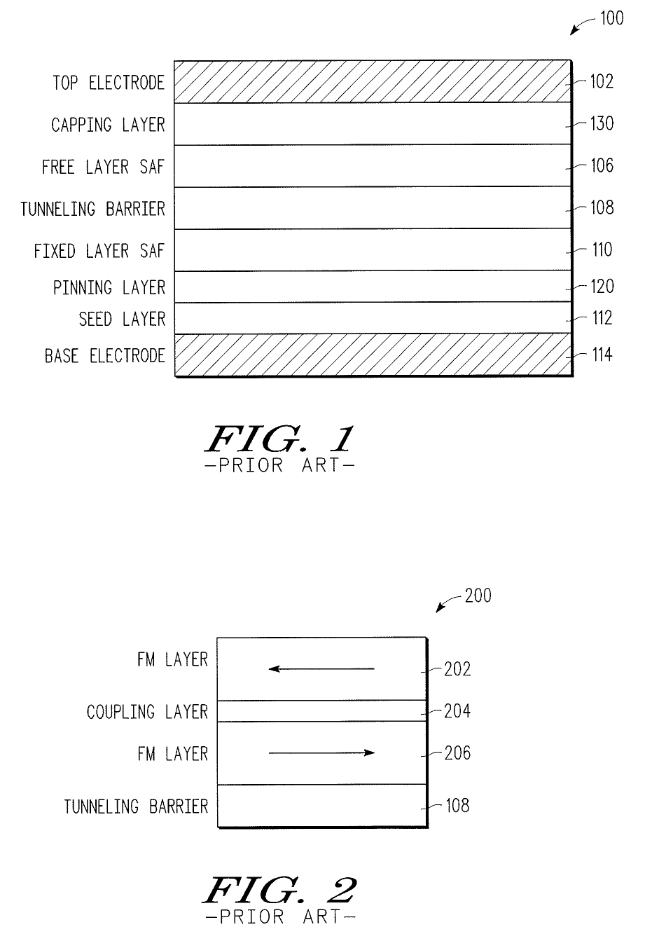

### DETAILED DESCRIPTION

In general, what is described herein are methods and apparatus for a magnetic tunnel junction (MTJ) comprising a synthetic antiferromagnet (SAF) structure formed on a tunnel barrier layer, wherein the SAF includes a plurality (e.g., three or more) ferromagnetic layers antiferromagnetically or ferromagnetically coupled through a plurality of respective coupling layers. The bottom ferromagnetic layer adjacent the tunnel barrier layer has a large spin polarization (typically, accompanying with high intrinsic anisotropy field (Hₖᵢ)), while one or more of the remaining ferromagnetic layers have a low Hₖᵢ. In this way, by providing a multi-layer SAF that includes ferromagnetic layers having different anisotropy fields and spin polarizations, MR is improved while switching fields are reduced. In this multilayer SAF structure, the switching field H_{sw} is primarily determined by the Hₛₐₜ of the outer SAFs and the saturation limit for toggling the multilayer SAF is mainly controlled by Hₛₐₜ of the inner SAF, enabling a larger operating window and a wider operating temperature range.

The following detailed description is merely exemplary in nature and is not intended to limit the range of possible embodiments and applications. Furthermore, there is no intention to be bound by any theory presented in the preceding background or the following detailed description.

For simplicity and clarity of illustration, the drawing figures depict the general structure and/or manner of construction of the various embodiments. Descriptions and details of well-known features and techniques may be omitted to avoid unnecessarily obscuring other features. Elements in the drawings figures are not necessarily drawn to scale: the dimensions of some features may be exaggerated relative to other elements to assist improve understanding of the example embodiments.

Terms of enumeration such as “first,” “second,” “third,” and the like may be used for distinguishing between similar elements and not necessarily for describing a particular spatial or chronological order. These terms, so used, are interchangeable under appropriate circumstances. The embodiments of the invention described herein are, for example, capable of use in sequences other than those illustrated or otherwise described herein. Unless expressly stated otherwise, “connected” means that one element/node/feature is directly joined to (or directly communicates with) another element/node/feature, and not necessarily mechanically. Likewise, unless expressly stated otherwise, “coupled” means that one element/node/feature is directly or indirectly joined to (or directly or indirectly communicates with) another element/node/feature, and not necessarily mechanically.

The terms “comprise,” “include,” “have” and any variations thereof are used synonymously to denote non-exclusive inclusion. The terms “left,” right,” “in,” “out,” “front,” “back,” “up,” “down,” and other such directional terms are used to describe relative positions, not necessarily absolute positions in space. The term “exemplary” is used in the sense of “example,” rather than “ideal.”

In the interest of conciseness, conventional techniques, structures, and principles known by those skilled in the art may not be described herein, including, for example, standard MRAM processing techniques, fundamental principles of magnetism, and basic operational principles of memory devices. For the purposes of clarity, some commonly-used layers may not be illustrated in the drawings, including various protective cap layers, seed layers, and the underlying substrate (which may be a conventional semiconductor substrate or any other suitable structure).

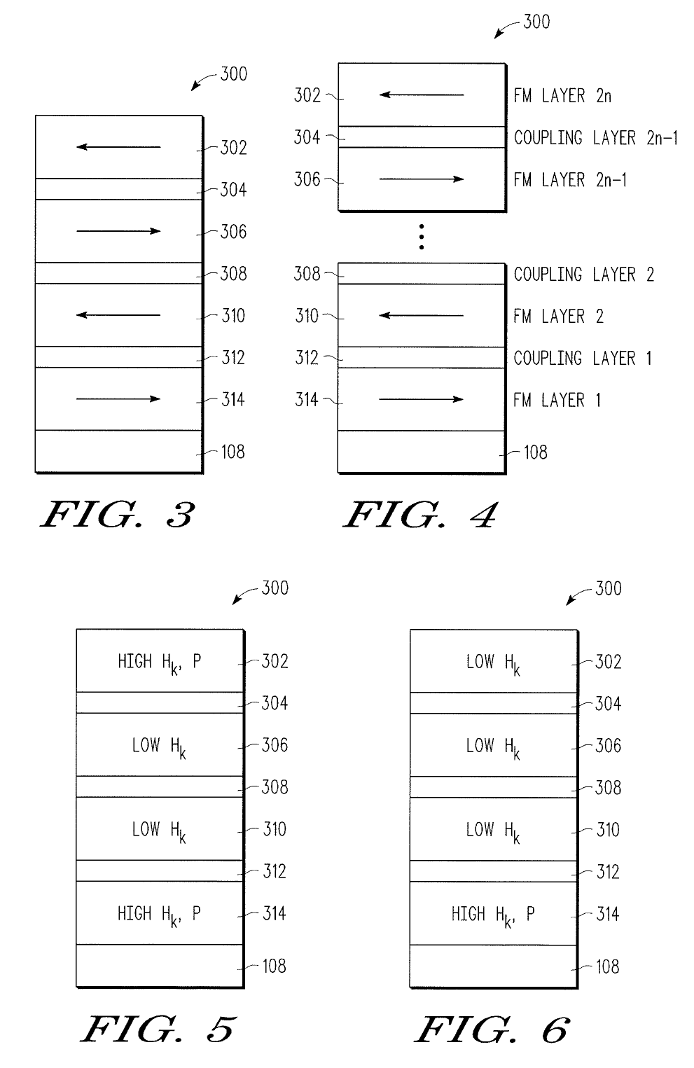

MTJs in accordance with various embodiments may include any number of ferromagnetic layers, and may be incorporated into a variety of structures, such as toggle MRAM, hard disk drive and magnetic sensors and the like. FIG. 3 depicts a SAF structure 300 formed on a tunnel barrier layer 108 in accordance with one embodiment. SAF 300 in this embodiment includes a three or more ferromagnetic layers (i.e., four ferromagnetic layers 302, 306, 310, and 314) separated and antiferromagnetically or ferromagnetically coupled to each other via respective coupling layers 304, 308, and 312, wherein the bottommost ferromagnetic layer 314 is formed adjacent to tunneling barrier (or “tunnel barrier”) 108. That is, these layers may be antifertomagnetically coupled, or layers 304 and 312 may be adjusted to provide a certain amount of ferromagnetic coupling while layer 308 provides antiferromagnetic (AF) coupling.

While the entire structure of FIG. 3 may be referred to as a SAF, it will be appreciated that the illustrated structure may be characterized as including multiple SAFs—i.e., one SAF comprising layers 310, 312, and 314, and another SAF comprising layers 302, 304, and 306. These two SAFs, often referred to as the outer SAFs, are antiferromagnetically coupled to each other via middle coupling layer 308. The SAF comprising layers 306, 308, and 310 is referred to as the center SAF. Thus, structure 300 is alternatively referred to as a multilayer-SAF, or “ML-SAF.”

The ferromagnetic layer adjacent to tunneling barrier 108 (layer 314) comprises a material with high spin polarization in order to produce high MR. Materials known in the art to have the highest spin polarization also have significantly higher Hₖᵢ than typical free layer materials such as the NiFe alloy known as Permalloy. Within ML-SAF 300, at least one of the ferromagnetic layers other than layer 314 are configured to have an anisotropy field (Hₖᵢ) that is lower than that of layer 314. By using multiple layers exhibiting different values of Hₖᵢ, a multilayer-SAF structure is formed which effectively increases Hₛₐₜ of the ML-SAF (and consequently the operating window) without increasing H_{sw}.

In this regard, as used herein, the term “low anisotropy field” refers to an anisotropy field of less than about 10 Oe, and the term “high anisotropy field” refers to an anisotropy field greater than about 10 Oe. In one embodiment, for example, ferromagnetic layer 314 comprises a material having an intrinsic anisotropy field greater than approximately 10 Oe, while one or more of ferromagnetic layers 302, 306, and 310 comprise a material (or materials) having an intrinsic anisotropy field less than approximately 10 Oe.

In general, ferromagnetic layer 314, which is adjacent tunneling barrier 108, is selected to exhibit high spin polarization and, consequently a high intrinsic anisotropy field, while one or more of the remaining layers exhibit a low anisotropy field. As is known in the art, the spin polarization of a structure measures the degree to which the spin (the intrinsic angular momentum of its particles) is aligned in a particular direction. This parameter is related to the band structure of the material used to make the layer, and is typically expressed in percent.

In one embodiment, ferromagnetic layer 314 comprises a NiFeCo alloy or CoFeB alloy—both of which are known to exhibit high Hₖᵢ and high polarization, and one or more of the remaining layers comprise NiFe, which exhibits a low Hₖᵢ. A variety of other materials may also be used. For example, the high Hₖᵢ material or materials may include a variety of other CoFe-based alloys. Similarly, the low Hₖᵢ material or materials may include a CoFeX alloy (where X is B, C, Zr, or Ta) and/or NiFeX (where X is Ta, Mo, or Cr). The thicknesses of the various ferromagnetic layers may be selected to achieve the applicable design goals. In an example embodiment, layers 302, 306, 310, and 314 have thicknesses ranging from 25 Å to 80 Å.

The coupling layers (e.g., coupling layers 304, 308, and 312) may comprise the same or different materials, and may have any desired thickness. Suitable materials include, for example, Ru, Os, Nb, Ir, Rh, Pt, Ta, Rh, Re, Ta, Cr, V and Pd, and/or combinations thereof. The thickness of the coupling layers may range from about 6-25 Å, depending upon the application.

Tunneling barrier 108 may comprise a variety of dielectric materials and may have any suitable structure. In one embodiment, for example, tunneling barrier layer 108 comprises an aluminum oxide (AlOₓ layer) having a thickness of about 6-15 Å.

While FIG. 3 depicts a SAF 300 with four ferromagnetic layers, the range of embodiments is not so limited. For example, as shown in FIG. 4, SAF structure 300 may include 2n ferromagnetic layers separated by 2n−1 coupling layers, where n is an integer greater than one. Stated another way, in one embodiment, the MTJ stack of the illustrated embodiment includes an even number of ferromagnetic layers and an odd number of coupling layers as shown. It has been determined that it is advantageous for n to be greater than one (e.g., n=2, as illustrated in FIG. 3).

FIG. 5 depicts an n=2 embodiment wherein outermost ferromagnetic layers 314 and 302 comprise a material having a high spin polarization and a high anisotropy field, and innermost ferromagnetic layers 306 and 310 comprise a material having a low anisotropy field. FIG. 6 depicts an alternate n=2 embodiment wherein only layer 314 has a high spin polarization and a high intrinsic anisotropy field, and all remaining layers 302, 306, and 310 have a low intrinsic anisotropy field.

Thus, in accordance with the above, by providing a ML-SAF that includes ferromagnetic layers having different spin polarization and different anisotropy fields as described, the MR of the MTJ is improved while switching fields are maintained comparable to structures made from only low-Hₖᵢ materials, resulting in a larger operating window and a wider operating temperature range than would be possible with prior art. Conventional MTJ fabrication techniques may be used, including, for example, standard physical vapor deposition techniques such as magnetron sputtering and ion-beam sputtering.

In summary, a magnetic tunnel junction (MTJ) structure in accordance with one embodiment includes a tunnel barrier layer and a synthetic antiferromagnet (SAF) structure formed adjacent the tunnel barrier layer, wherein the SAF comprises a plurality of ferromagnetic layers antifertomagnetically or ferromagnetically coupled by a plurality of respective coupling layers, wherein the plurality of ferromagnetic layers includes a first ferromagnetic layer adjacent the tunnel barrier layer, a second ferromagnetic layer, and a third ferromagnetic layer, wherein the first ferromagnetic layer has a first spin polarization and a first anisotropy field (Hₖᵢ) that are greater than that of at least one of the second and third fermomagnetic layers.

In one embodiment, the plurality of ferromagnetic layers comprises 2n ferromagnetic layers and the plurality of coupling layers comprises 2n−1 coupling layers, wherein n is an integer greater than one. In a particular embodiment, n=2. The first anisotropy field Hₖᵢ of the first ferromagnetic layer may be greater than approximately 10 Oe. In a one embodiment, the first ferromagnetic layer comprises NiFeCo and/or the first ferromagnetic layer comprises CoFeB. In a particular embodiment, each of the plurality of coupling layers comprises Ru.

A further embodiment includes a fourth ferromagnetic layer, wherein the first and fourth ferromagnetic layers have a high spin polarization and a high anisotropy field, and the second and third ferromagnetic layers have a low spin polarization and a low anisotropy field. The first ferromagnetic layer may have a high spin polarization and a high anisotropy field, and the second, third, and fourth ferromagnetic layers have a low spin polarization and a low anisotropy field.

A method in accordance with one embodiment includes: providing a tunnel barrier layer; forming a first ferromagnetic layer on the tunnel barrier layer; forming a first coupling layer on the first ferromagnetic layer; forming a second ferromagnetic layer on the first coupling layer; forming a second coupling layer on the second ferromagnetic layer; and forming a third ferromagnetic layer on the second coupling layer; wherein the first ferromagnetic layer is formed such that it has a first spin polarization and a first anisotropy field (Hₖᵢ) that is higher than that of at least one of the second and third ferromagnetic layers. In various embodiments, forming the first ferromagnetic layer includes forming a layer having an anisotropy field Hₖᵢ greater than approximately 10 Oe, forming the first ferromagnetic layer includes forming a layer of NiFeCo, forming the first ferromagnetic layer includes forming a layer of CoFeB, and/or forming the first coupling layer includes forming a layer of Ru.

On embodiment includes forming a fourth ferromagnetic layer such that the first and fourth ferromagnetic layers have a high spin polarization and a high anisotropy field, and the second and third fen-omagnetic layers have a low spin polarization and a low anisotropy field.

One embodiment includes forming a fourth ferromagnetic layer such that the first ferromagnetic layer has a high spin polarization and a high anisotropy field, and the second, third, and fourth ferromagnetic layers have a low spin polarization and a low anisotropy field.

A toggle MRAM device in accordance with one embodiment comprises: a first electrode; a seed layer formed on the first electrode; a pinning layer formed on the seed layer; a fixed layer synthetic antiferromagnet (SAF) formed on the pinning layer; a tunneling barrier formed on the fixed layer SAF; a free layer SAF formed on the tunneling barrier, the free layer SAF comprising 2n (e.g., n=2) ferromagnetic layers antiferromagnetically or feromagnetically coupled by 2n−1 respective coupling layers, wherein n is an integer greater than 1, and wherein a first ferromagnetic layer adjacent the tunneling barrier has a first spin polarization and a first anisotropy field (Hₖᵢ) that is higher than that of at least one of the remaining ferromagnetic layers; a cap layer formed on the free layer SAF; and a second electrode formed on the cap layer.

The first ferromagnetic layer may comprise a material selected from the group consisting of NiFeCo and CoFeB, and wherein at least one of the remaining ferromagnetic layers comprises NiFe. In one embodiment, the first ferromagnetic layer has an intrinsic anisotropy field Hₖᵢ greater than about 10 Oe. In one embodiment, each of the coupling layers comprises a material selected from the group consisting of Ru, Os, Nb, Ir, Rh, Pt, Ta, Rh, Re, Ta, Cr, V, Pd, and/or combinations thereof.

As is known in the art, in forming an MRAM device, the ML-SAF structure is typically deposited as blanket film layers and subsequently patterned into many individual devices using conventional lithographic and etching techniques. Once the ML-SAF is patterned, the various layers couple through magnetostatic coupling in addition to the coupling associated with the coupling layers previously described. To form SAF structure, at least two of the multiple ferromagnetic layers will have a total coupling, from all sources, that is antiferromagnetic (AF). Devices of different sizes and optimized for different properties may have various combinations of FM and AF coupling from the various layers, but toggle MRAM will have at least two layers exhibiting AF total coupling.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the embodiments in any way. Rather, the foregoing detailed description will provide those skilled in the art with a convenient road map for implementing an exemplary embodiment, it being understood that various changes may be made in the function and arrangement of elements described in an exemplary embodiment without departing from the scope as set forth in the appended claims.

1. A magnetic tunnel junction (MTJ) structure comprising:
a tunnel barrier layer; and
a synthetic antifertomagnet (SAF) structure formed adjacent the tunnel barrier layer, wherein the SAF comprises a plurality of ferromagnetic layers antiferromagnetically or ferromagnetically coupled by a plurality of respective coupling layers, wherein the plurality of ferromagnetic layers includes a first ferromagnetic layer adjacent the tunnel barrier layer, a second ferromagnetic layer, and a third ferromagnetic layer, wherein the first ferromagnetic layer has a first spin polarization and a first intrinsic anisotropy field (Hₖᵢ) that are greater than that of at least one of the second and third ferromagnetic layers.

2. The MTJ structure of claim 1, wherein the plurality of ferromagnetic layers comprises 2n ferromagnetic layers and the plurality of coupling layers comprises 2n−1 coupling layers, wherein n is an integer greater than one.

3. The MTJ structure of claim 2, wherein n=2.

4. The MTJ structure of claim 1, wherein the first anisotropy field of the first ferromagnetic layer is greater than approximately 10 Oe.

5. The MTJ structure of claim 1, wherein the first ferromagnetic layer comprises NiFeCo.

5. The MTJ structure of claim 1, wherein the first ferromagnetic layer comprises CoFeB.

6. The MTJ structure of claim 1, wherein the each of the plurality of coupling layers comprises Ru.

7. The MTJ structure of claim 1, further including a fourth ferromagnetic layer, wherein the first and fourth ferromagnetic layers have a high spin polarization and a high intrinsic anisotropy field, and the second and third ferromagnetic layers have a low spin polarization and a low intrinsic anisotropy field.

8. The MTJ structure of claim 1, further including a fourth ferromagnetic layer, wherein the first ferromagnetic layer has a high spin polarization and a high intrinsic anisotropy field, and the second, third, and fourth ferromagnetic layers have a low spin polarization and a low intrinsic anisotropy field.

9. A method for forming a magnetic tunnel junction, comprising:
providing a tunnel barrier layer;
forming a first ferromagnetic layer on the tunnel barrier layer;
forming a first coupling layer on the first ferromagnetic layer;
forming a second ferromagnetic layer on the first coupling layer;
forming a second coupling layer on the second ferromagnetic layer; and
forming a third ferromagnetic layer on the second coupling layer;
wherein the first ferromagnetic layer is formed such that it has a first spin polarization and a first intrinsic anisotropy field (Hₖᵢ) that is higher than that of at least one of the second and third ferromagnetic layers.

10. The method of claim 9, wherein forming the first ferromagnetic layer includes forming a layer having an anisotropy field greater than approximately 10 Oe.

11. The method of claim 9, wherein forming the first ferromagnetic layer includes forming a layer of NiFeCo.

12. The method of claim 9, wherein forming the first ferromagnetic layer includes forming a layer of CoFeB.

13. The method of claim 9, wherein forming the first coupling layer includes forming a layer of Ru.

14. The method of claim 9, further including forming a fourth ferromagnetic layer such that the first and fourth ferromagnetic layers have a high spin polarization and a high intrinsic anisotropy field, and the second and third ferromagnetic layers have a low spin polarization and a low intrinsic anisotropy field.

15. The method of claim 9, further including a forming a fourth ferromagnetic layer such that the first ferromagnetic layer has a high spin polarization and a high intrinsic anisotropy field, and the second, third, and fourth ferromagnetic layers have a low spin polarization and a low intrinsic anisotropy field.

16. A toggle MRAM device comprising:
a first electrode;
a seed layer formed on the first electrode;
a pinning layer formed on the seed layer
a fixed layer synthetic antiferromagnet (SAF) formed on the pinning layer;
a tunneling barrier formed on the fixed layer SAF;
a free layer SAF formed on the tunneling barrier, the free layer SAF comprising 2n ferromagnetic layers antiferromagnetically or ferromagnetically coupled by 2n−1 respective coupling layers, wherein n is an integer greater than 1, and wherein a first ferromagnetic layer adjacent the tunneling barrier has a first spin polarization and a first intrinsic anisotropy field (Hₖᵢ) that is higher than that of at least one of the other ferromagnetic layers;
a cap layer formed on the free layer SAF; and
a second electrode formed on the cap layer.

17. The toggle MRAM device of claim 16, wherein the first ferromagnetic layer comprises a material selected from the group consisting of NiFeCo and CoFeB, and wherein at least one of the remaining ferromagnetic layers comprises NiFe.

18. The toggle MRAM device of claim 16, wherein n=2.

19. The toggle MRAM device of claim 16, wherein the first ferromagnetic layer has an anisotropy field greater than about 10 Oe.

20. The toggle MRAM device of claim 16, wherein each of the coupling layers comprises a material selected from the group consisting of Ru, Os, Nb, Ir, Rh, Pt, Ta, Rh, Re, Ta, Cr, V, and Pd.
